(19) United States
(12) Patent Application Publication
(10) Pub. No.: US 2026/0171351 A1
(43) Pub. Date: Jun. 18, 2026

(54) LOCAL OBSERVATION METHOD, PROGRAM, STORAGE MEDIUM, AND ELECTRON BEAM APPLICATOR

(71) Applicant: Photo electron Soul Inc., Nagoya-shi, Aichi (JP)

(72) Inventors: Tomohiro NISHITANI, Nagoya-shi, Aichi (JP); Yuta ARAKAWA, Nagoya-shi, Aichi (JP)

(21) Appl. No.: 19/127,081

(22) PCT Filed: Oct. 31, 2023
(86) PCT No.: PCT/JP2023/039260

§ 371 Date: May 2, 2025

(30) Foreign Application Priority Data
Nov. 4, 2022 (JP) 2022-177548

(51) Int. Cl. H01J 37/285

(52) U.S. Cl. CPC H01J 37/285; H01J 2237/06333

(57) ABSTRACT

The present invention addresses the problem of providing a local observation method in which, when a first area-to-be-irradiated is irradiated with an electronic beam, a second area, which is influenced by same, can be locally observed, and an electron beam application device for executing the location observation method. Provided is a local observation method for an object-to-be-irradiated in an electron beam application device, wherein, when a first area-to-be-irradiated is irradiated with an electron beam, the method is for observing a second area influenced by same. The electron beam application device comprises: a light source; a photocathode which generates, in response to receiving excitation light irradiated from the light source, electrons capable of being emitted; an anode which can form an electric field with the photocathode, draws, by means of the formed electric field, the electrons capable of being emitted, and forms the electron beam; a detector which detects emissions emitted from the object-to-be-irradiated that has been irradiated with the electron beam, and generates a detection signal; and a control unit. The local observation method causes the control unit to execute: a position information setting step for setting position information about the first area and the second area in the object-to-be-irradiated; a first electron beam parameter setting step for setting parameters of the electron beam to irradiate the first area; a first electron beam irradiation condition setting step for setting, on the basis of a positional relationship between the first area and the second area, irradiation conditions of the electron beam that is to irradiate the first area and has the first electron beam parameters and the electron beam to irradiate the second area; an electron beam irradiation step for irradiating the first area and the second area with the electron beams on the basis of the irradiation conditions set in the first electron beam irradiation condition setting step; and a detection step for detecting, by means of the detector, emission amounts of the emissions emitted from the first and second areas irradiated with the electron beam, and generating the detection signal.

### TECHNICAL FIELD

The present disclosure of the present application relates to a local observation method for an irradiation target using an electron beam applicator, a program for implementing a local observation method with an electron beam applicator, a storage medium storing the program, and an electron beam applicator.

### BACKGROUND ART

Electron beam applicators such as an electron gun equipped with a photocathode and an electron microscope, a free electron laser accelerator, an inspection device, or the like including the electron gun are known.

Photocathodes can emit an electron beam in accordance with the intensity of received excitation light. An electron gun that makes the most of characteristics of such a photocathode to enable emission of an electron beam having a desired electron beam parameter by using only components of the electron gun including the photocathode and also an electron beam applicator equipped with such an electron gun are known (see Patent Literature 1).

### CITATION LIST

### Patent Literature

Patent Literature 1: Japanese U.S. Pat. No. 6,968,473

### SUMMARY OF INVENTION

### Technical Problem

The use of the electron beam applicator equipped with the electron gun disclosed in Patent Literature 1 enables emission of an electron beam having a desired electron beam parameter to a desired portion of a single irradiation target. It is thus possible to obtain advantages of elimination of charging-up of a sample, which is an irradiation target, more sharpened unevenness of a sample, and the like. The present inventors assume that, in observing an irradiation target by using an electron beam applicator, in particular, in irradiating a particular region (first region) of an irradiation target with an electron beam, there arises a need for suitably observing a second region affected by the irradiation in addition to observing the shape such as unevenness of the irradiation target.

However, the electron beam applicator equipped with the electron gun disclosed in Patent Literature 1 merely enables emission of an electron beam having a desired electron beam parameter to a desired portion of a single irradiation target by using only the components of the electron gun including the photocathode. Patent Literature 1 does not disclose how to suitably observe the second region affected by the irradiation on the first region with an electron beam.

The present application has been made to solve the above problem. According to an intensive study, it has been newly found that, in an electron beam applicator, when irradiating a first region of an irradiation target with an electron beam, it is possible to locally observe a second region affected by the irradiation by (1) setting a parameter (first electron beam parameter) of an electron beam that irradiates the first region, (2) setting irradiation conditions of an electron beam that irradiates the first region and has a first electron beam parameter and an electron beam that irradiates the second region based on position information on the first region and the second region of an irradiation target, (3) irradiating the first region and the second region with electron beams based on the set irradiation conditions, and (4) by a detector, determining the emission quantity of an emission substance emitted from the first region and the second region irradiated with the electron beams and generating detection signals.

That is, the disclosure in the present application relates to a local observation method for, when irradiating a first region of an irradiation target with an electron beam, locally observing a second region affected by the irradiation, a program for implementing a local observation method with an electron beam applicator, a storage medium storing the program, and an electron beam applicator.

### Solution to Problem

The present application relates to a local observation method, a program for implementing a local observation method with an electron beam applicator, a storage medium storing the program, and an electron beam applicator illustrated below.

(1) A local observation method for an irradiation target in an electron beam applicator, the local observation method being a method for, when irradiating a first region of the irradiation target with an electron beam, observing a second region affected by the irradiation,
wherein the electron beam applicator includes
a light source,
a photocathode configured to generate releasable electrons in response to receiving excitation light emitted from the light source,
an anode configured to form an electric field between the photocathode and the anode and extract the releasable electrons by the formed electric field to form an electron beam,
a detector configured to detect an emission substance emitted from the irradiation target irradiated with the electron beam and generate a detection signal, and
a control unit, and
wherein the local observation method implements control such that the control unit performs:
a position information setting step of setting position information on the first region and the second region in the irradiation target;
a first electron beam parameter setting step of setting a parameter of an electron beam that irradiates the first region;
an electron beam irradiation condition first setting step of, based on a positional relationship between the first region and the second region, setting irradiation conditions of an electron beam that irradiates the first region and has a first electron beam parameter and an electron beam that irradiates the second region;
an electron beam irradiation step of irradiating the first region and the second region with electron beams based on the irradiation conditions set in the electron beam irradiation condition first setting step; and
a detection step of determining, by the detector, an emission quantity of an emission substance emitted from the first region and the second region irradiated with the electron beams and generating a detection signal.
   (2) The local observation method according to (1) above further including a first region and second region position information acquisition step before the position information setting step,
wherein the first region and second region position information acquisition step performs:
a step of irradiating the irradiation target with an electron beam,
a detection step of determining, by the detector, an emission quantity of an emission substance emitted from an irradiated region irradiated with the electron beam and generating a detection signal, and
a detection data output step of outputting the detection signal generated in the detection step in association with position information on the irradiated region, and
wherein the position information setting step is performed based on detection data associated with the position information on the irradiated region output in the detection data output step.
   (3) The local observation method according to (1) above,
wherein the electron beam applicator further includes an electron beam deflector configured to scan the irradiation target with the electron beam, and
wherein the control unit,
   in the electron beam irradiation condition first setting step,
   performs an electron beam irradiation timing first setting step of, based on the positional relationship between the first region and the second region, setting an irradiation timing of an electron beam that irradiates the first region and has a first electron beam parameter and an irradiation timing of an electron beam that irradiates the second region, and
   in the electron beam irradiation step,
   irradiates the first region and the second region with electron beams at timings set in the electron beam irradiation timing first setting step by controlling the electron beam deflector.
      (4) The local observation method according to (2) above,
wherein the electron beam applicator further includes an electron beam deflector configured to scan the irradiation target with the electron beam, and
wherein the control unit,
   in the electron beam irradiation condition first setting step,
   performs an electron beam irradiation timing first setting step of, based on the positional relationship between the first region and the second region, setting an irradiation timing of an electron beam that irradiates the first region and has a first electron beam parameter and an irradiation timing of an electron beam that irradiates the second region, and
   in the electron beam irradiation step,
   irradiates the first region and the second region with electron beams at timings set in the electron beam irradiation timing first setting step by controlling the electron beam deflector.
      (5) The local observation method according to (3) above, wherein the electron beam irradiation timing first setting step sets,
based on a time of appearance of an effect on the second region and a duration of the effect after the first region is irradiated with an electron beam in addition to the positional relationship between the first region and the second region,
an irradiation timing of an electron beam that irradiates the first region and has a first electron beam parameter and an irradiation timing of an electron beam that irradiates the second region.
   (6) The local observation method according to (1) above further including an observation-use electron beam parameter setting step of setting a parameter of an electron beam that irradiates the second region.
   (7) The local observation method according to (1) above, wherein an electron beam with which the first region is irradiated and an electron beam with which the second region is irradiated are
extracted from different locations of a single photocathode, or
extracted from different photocathodes.
   (8) The local observation method according to (1) above, wherein the control unit,
in the electron beam irradiation condition first setting step,
performs an electron beam irradiation size and/or shape first setting step of, based on the positional relationship between the first region and the second region, setting a size and/or a shape of an electron beam that irradiates the first region and has a first electron beam parameter and a size and/or a shape of an electron beam that irradiates the second region, and
in the electron beam irradiation step,
irradiates the first region and the second region with electron beams having sizes and/or shapes set in the electron beam irradiation size and/or shape first setting step.
   (9) The local observation method according to (2) above, wherein the control unit,
in the electron beam irradiation condition first setting step,
performs an electron beam irradiation size and/or shape first setting step of, based on the positional relationship between the first region and the second region, setting a size and/or a shape of an electron beam that irradiates the first region and has a first electron beam parameter and a size and/or a shape of an electron beam that irradiates the second region, and
in the electron beam irradiation step,
irradiates the first region and the second region with electron beams having sizes and/or shapes set in the electron beam irradiation size and/or shape first setting step.
   (10) The local observation method according to (1) above, wherein the local observation method implements control such that, after performing the detection step according to (1) above, the control unit performs:
a second electron beam parameter setting step of, for a parameter of an electron beam that irradiates the first region, setting an electron beam parameter different from the parameter set in the first electron beam parameter setting step;
an electron beam irradiation condition second setting step of, based on the positional relationship between the first region and the second region, setting irradiation conditions of an electron beam that irradiates the first region and has a second electron beam parameter and an electron beam that irradiates the second region;
an electron beam irradiation step of irradiating the first region and the second region with electron beams based on the irradiation conditions set in the electron beam irradiation condition second setting step; and
a detection step of determining, by the detector, an emission quantity of an emission substance emitted from the first region and the second region irradiated with the electron beams and generating a detection signal.
   (11) The local observation method according to (1) above,
wherein the irradiation target is a metal oxide semiconductor field effect transistor,
wherein the first region is the gate,
wherein the second region is the drain, and
wherein a state of current flowing between the source and the drain is observed by irradiating the first region with an electron beam.
   (12) The local observation method according to (1) above, wherein the electron beam applicator is
a scanning electron microscope,
an electron beam inspection device,
an X-ray analyzer,
a transmission electron microscope, or
a scanning transmission electron microscope.
   (13) A program that causes the control unit of the electron beam applicator to perform each step according to any one of (1) to (12).
   (14) A computer readable storage medium storing the program according to (13) above.
   (15) An electron beam applicator including:
a light source;
a photocathode configured to generate releasable electrons in response to receiving excitation light emitted from the light source;
an anode configured to form an electric field between the photocathode and the anode and extract the releasable electrons by the formed electric field to form an electron beam;
a detector configured to detect an emission substance emitted from an irradiation target irradiated with the electron beam and generate a detection signal; and
a control unit,
wherein the program according to (13) above is stored in the control unit.

### Advantageous Effects of Invention

The local observation method using the electron beam applicator disclosed in the present application that, when irradiating a first region of an irradiation target with an electron beam, can observe a second region affected by the irradiation.

### BRIEF DESCRIPTION OF DRAWINGS

FIG. 1 is a diagram schematically illustrating an electron beam applicator 1 according to a first embodiment.

FIG. 2 is a diagram illustrating an overview of a local observation method according to the first embodiment, which is a diagram of an irradiation target S when viewed from a photocathode 3 side.

FIG. 3 is a flowchart of the local observation method according to the first embodiment.

FIG. 4 is a diagram illustrating an overview of an example of control performed by a control unit 6 in order to have a set electron beam parameter in an electron beam applicator 1 according to the first embodiment.

FIG. 5 is an enlarged view of the part of a photocathode 3 of an electron beam applicator 1A according to a second embodiment.

FIG. 6 represents diagrams of an irradiation target S when viewed from the photocathode 3 side in the electron beam applicator 1A according to the second embodiment.

FIG. 7 is an enlarged view of the part of the photocathode 3 of an electron beam applicator 1B and the irradiation target S according to a third embodiment.

FIG. 8 is a visual representation illustrating a view of a sample prepared in an Example.

FIG. 9 is a diagram illustrating an overview of a local observation method of Example 2.

FIG. 10 is a diagram illustrating a result obtained from a SEM image when a local observation method of Example 3 is performed.

### DESCRIPTION OF EMBODIMENTS

A local observation method, a program for implementing a local observation method with an electron beam applicator, a storage medium storing the program, and an electron beam applicator will be described below in detail with reference to the drawings. Note that, in the present specification, members having the same type of functions are labeled with the same or similar references. Further, duplicated description for the members labeled with the same or similar references may be omitted.

Further, the position, size, range, or the like of respective components illustrated in the drawings may be depicted differently from the actual position, size, range, or the like for easier understanding. Thus, the disclosure in the present application is not necessarily limited to the position, size, range, or the like disclosed in the drawings.

### First Embodiment of Electron Beam Applicator and First Embodiment of Local Observation Method

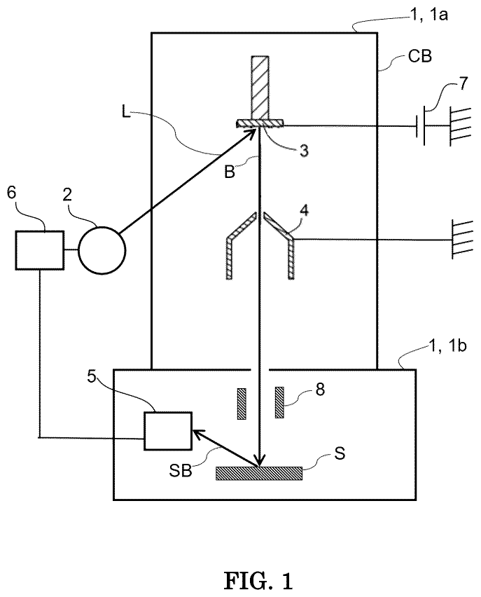

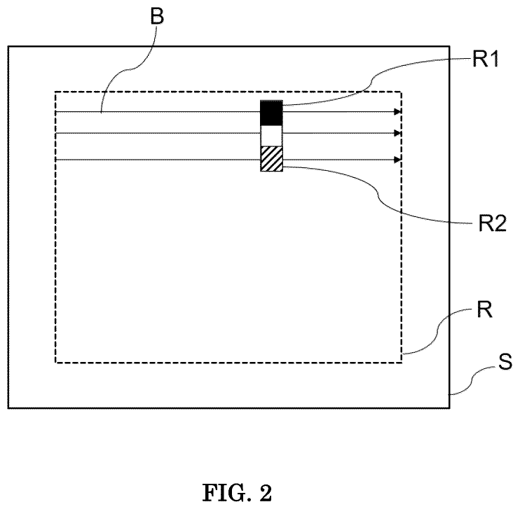

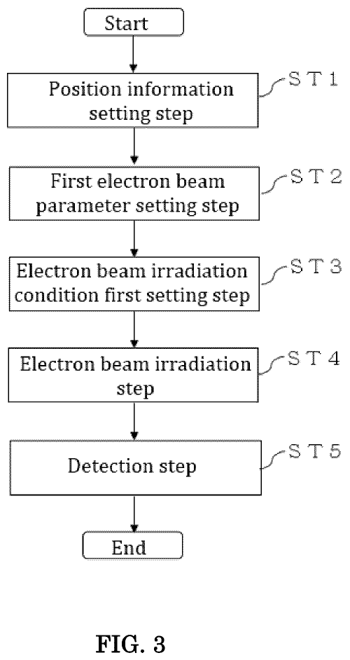

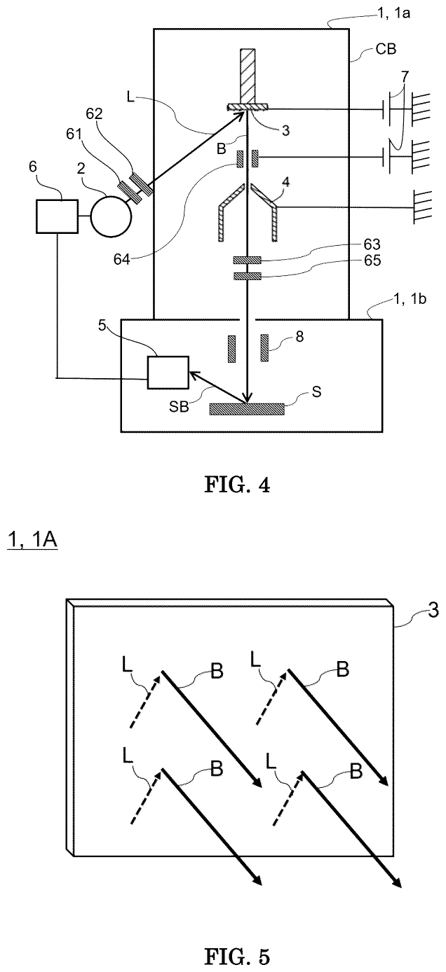

An electron beam applicator 1 according to the first embodiment and a local observation method according to the first embodiment will be described with reference to FIG. 1 to FIG. 4. FIG. 1 is a diagram schematically illustrating the electron beam applicator 1 according to the first embodiment. FIG. 2 is a diagram illustrating an overview of the local observation method, which is a diagram of an irradiation target S when viewed from a photocathode 3 side. FIG. 3 is a flowchart of the local observation method. FIG. 4 is a diagram illustrating an overview of an example of control performed by a control unit 6 in order to have a set electron beam parameter.

The electron beam applicator 1 according to the first embodiment illustrated in FIG. 1 includes at least a light source 2, a photocathode 3, an anode 4, a detector 5, a control unit 6, and an electron beam deflector 8. Note that FIG. 1 illustrates an example in which the electron beam applicator 1 is formed separately of an electron gun portion 1a and a counterpart device 1b (the remaining portion of the electron beam applicator 1 when the electron gun portion 1a is removed). Alternatively, the electron beam applicator 1 may be formed in an integrated manner. Further, the electron beam applicator 1 may be optionally, additionally provided with a power supply 7 for generating an electric field between the photocathode 3 and the anode 4. Furthermore, although illustration is omitted, a known component in accordance with the type of the electron beam applicator 1 may be included. Note that, although the electron beam deflector 8 is an essential requirement in the first embodiment, the electron beam deflector 8 is not an essential requirement in a third embodiment described later.

The light source 2 is not particularly limited as long as it can irradiate the photocathode 3 with excitation light L to cause emission of the electron beam B. The light source 2 may be, for example, a high power (watt class), high frequency (several hundred MHz), ultrashort pulse laser light source, a relatively inexpensive laser diode, an LED, or the like. The excitation light L for irradiation can be either pulsed light or continuous light and can be adjusted as appropriate in accordance with purposes. Note that, in the example illustrated in FIG. 1, the light source 2 is arranged outside a vacuum chamber CB, and a first face (a face on the anode 4 side) side of the photocathode 3 is irradiated with the excitation light L. Alternatively, the light source 2 may be arranged inside the vacuum chamber CB. Further, a second face (a face on the opposite side of the anode 4) side of the photocathode 3 may be irradiated with the excitation light L.

The photocathode 3 generates releasable electrons in response to receiving the excitation light L irradiated from the light source 2. The principle of the photocathode 3 generating releasable electrons in response to receiving the excitation light L is well known (for example, see Japanese U.S. Pat. No. 5,808,021 and the like).

The photocathode 3 is formed of a substrate of quartz glass, sapphire glass, or the like and a photocathode film (not illustrated) adhered to the first face (the face on the anode 4 side) of the substrate. The photocathode material for forming the photocathode film is not particularly limited as long as it can generate releasable electrons in response to irradiation with excitation light and may be a material requiring EA surface treatment, a material not requiring EA surface treatment, or the like. The material requiring EA surface treatment may be, for example, Group III-V semiconductor materials or Group II-VI semiconductor materials. Specifically, the material may be AIN, Ce2Te, GaN, a compound of one or more types of alkaline metals and Sb, or AlAs, GaP, GaAs, GaSb, InAs, or the like, and a mixed crystal thereof, or the like. The material may be a metal as another example and specifically may be Mg, Cu, Nb, LaB6, SeB6, Ag, or the like. The photocathode 3 can be fabricated by applying EA surface treatment on the photocathode material described above. For the photocathode 3, suitable selection of the semiconductor material or the structure thereof makes it possible not only to select excitation light in a range from near-ultraviolet to infrared wavelengths in accordance with gap energy of the semiconductor but also to achieve electron beam source performance (quantum yield, durability, monochromaticity, time response, spin polarization) in accordance with the use of the electron beam.

Further, the material not requiring EA surface treatment may be, for example, a single metal, an alloy, or a metal compound of Cu, Mg, Sm, Tb, Y, or the like or diamond, WBaO, Cs₂Te, or the like. The photocathode not requiring EA surface treatment can be fabricated by a known method (for example, see Japanese U.S. Pat. No. 3,537,779 and the like). The content disclosed in Japanese U.S. Pat. No. 3,537,779 is incorporated in the present specification in its entirety by reference.

Note that, regarding the reference to “photocathode” and “cathode” in the present specification, “photocathode” may be used when the reference in question means emission of the electron beam, and “cathode” may be used when the reference in question means the counter electrode of an “anode”. Regarding the reference numeral, however, “3” is used for both cases of “photocathode” and “cathode”.

The anode 4 is not particularly limited as long as it can generate an electric field together with the cathode 3, and any anode 4 generally used in the field of electron guns can be used. When an electric field is formed between the cathode 3 and the anode 4, the releasable electrons generated by irradiation with the excitation light L are extracted from the photocathode 3, and thereby the electron beam B is formed.

Although FIG. 1 illustrates the example in which the power supply 7 is connected to the cathode 3 in order to form an electric field between the cathode 3 and the anode 4, the arrangement of the power supply 7 is not particularly limited as long as a potential difference occurs between the cathode 3 and the anode 4.

The detector 5 determines the emission quantity of an emission substance SB emitted from the irradiation target S irradiated with the electron beam B. The emission substance SB means a signal issued from the irradiation target S in response to irradiation with the electron beam B and may represent, for example, secondary electrons, reflected electrons, characteristic X-rays, Auger electrons, cathodoluminescence, transmitted electrons, or the like. The detector 5 is not particularly limited as long as it can detect emission of these emission substance SB, and a known detector and a known detection method can be used.

The control unit 6 may be a processor (CPU) or otherwise a general-purpose computer or the like equipped with a CPU.

The electron beam deflector 8 scans the irradiation target S with a formed electron beam B. As the electron beam deflector 8, a known device such as a deflecting electrode can be used that generates an electric field in a direction intersecting the traveling direction of the electron beam B.

Next, the local observation method disclosed in the present application (in other words, control details and program contents in the control unit 6 provided to the electron beam applicator 1) will be described with reference to FIG. 2 and FIG. 3. FIG. 2 is a diagram of the irradiation target S when viewed from the photocathode 3 side. FIG. 3 is a flowchart of the local observation method.

The local observation method includes a position information setting step (ST1), a first electron beam parameter setting step (ST2), an electron beam irradiation condition first setting step (ST3), an electron beam irradiation step (ST4), and a detection step (ST5).

The position information setting step (ST1) is to set position information of the first region R1 and the second region R2 in the irradiation target S. The first region R1 is a region that affects another region (second region) when irradiated with the electron beam B, in other words, when charges are injected to the first region R1. Further, the second region R2 is a region subjected to some effect due to irradiation of the first region R1 with the electron beam B. The first region R1 and the second region R2 are not particularly limited as long as they are subjected to some effect due to irradiation with the electron beam B as described above. For example, the irradiation target (sample) S corresponding to the first region and the second region may be, but is not limited to, a metal oxide semiconductor field effect transistor (MOSFET), a solar cell, an all-solid-state battery, an organic EL device, a tubulin, a synapse, or the like.

In a case of a MOSFET, the first region R1 may be the gate, and the second region R2 may be the drain as an example. For example, in a case of an nMOS, when the gate, which is the first region R1, is irradiated with the electron beam B, electrons that are carriers move from the source to the drain. However, when the electron beam parameter of the electron beam B to irradiate the gate is set weaker (or otherwise emission of the electron beam is turned OFF), electrons will no longer move from the source to the drain, and a SEM image of the drain, which is the second region R2, will be darker. Although illustrated in detail in Examples described later, in a case of an nMOS, by changing the intensity of the electron beam B to irradiate the gate (first region R1), in other words, changing the quantity of charges to be injected, it is possible to observe the state where electrons are moving from the source to the drain as brightness of the drain. Note that, when “a state where electrons are moving”, that is, “a state where current is flowing” is referred in the present specification, this also means a change in the amount of flowing current in addition to there being a flow of current (ON) and there being no flow of current (OFF). Note that, in a case of a pMOS, carriers are holes, and current is carried by the holes.

Solar cells, all-solid-state batteries, and organic EL devices are devices in which electrons, holes, ions, or the like move due to accumulation of charges. As described above, the local observation method disclosed in the present application may be any method in which the emission quantity of an emission substance SB emitted from the second region R2 changes due to irradiation of the first region R1 with the electron beam B. In a case of a solar cell, an all-solid-state battery, or an organic EL device, a portion that is a point from which electrons, holes, ions, or the like move due to accumulation of charges can be a first region R1, and a portion to which electrons, holes, ions, or the like move can be the second region R2.

A microtube is a protein structure forming a cytoskeleton within a cell, and it is known that the structure thereof changes in accordance with temperatures. For example, when a certain portion around a microtube is irradiated with the electron beam B, the microtube is heated due to a rise in the temperature of the portion caused by the energy of the electron beam B. It is therefore sufficient to irradiate the certain portion around the microtube as the first region R1 with the electron beam B, define the remaining portion of the tubulin as the second region R2, and observe polymerization/depolymerization reaction of the microtube.

A synapse corresponds to a junction site and its structure formed between nerve cells or between a muscle fiber (myofiber), a nerve cell, and another type cell and related to neural activity such as signal transduction. In a case of a synapse, for example, a presynaptic cell, which is a cell that transmits a signal, can be the first region R1, and a postsynaptic cell, which is a cell that receives a signal, can be the second region R2. It is sufficient to observe a change in the quantity of an emission substance SB emitted from the second region R2, because the cell membrane potential and an ion channel are locally affected by irradiation of the first region R1 with the electron beam B.

Note that the MOSFET, the solar cell, the all-solid-state battery, the organic EL device, the tubulin, and the synapse described above are mere examples of the local observation method of the present application. As described later, although the local observation method disclosed in the present application is to determine the emission quantity of emission substance SB emitted from the first region R1 and the second region R2 irradiated with the electron beams B, the emission substance SB to be detected may be, for example, secondary electrons, reflected electrons, characteristic X-rays, Auger electrons, cathodoluminescence, transmitted electrons, or the like. Therefore, when “when irradiating a first region of an irradiation target with an electron beam, to observe (observing) the second region affected by the irradiation” is referred in the present specification, “being affected” means that irradiation of the first region R1 of the irradiation target S with the electron beam B changes the emission quantity of the emission substance SB (for example, secondary electrons, reflected electrons, characteristic X-rays, Auger electrons, cathodoluminescence, transmitted electrons, or the like) emitted from the second region R2 detected by the detector 5.

Note that, although one second region R2 is present in the example illustrated in FIG. 2, the second region R2 is not particularly limited in terms of the number of regions and/or the shape of each region as long as it is or they are regions affected by the irradiation when the first region R1 is irradiated with the electron beam B, as described above. For example, two, three, four, five or more second regions R2 may be present for one first region R1. Further, regarding the shape, for example, when the irradiation target S is planar, the second region R2 may be formed in an annular shape about the first region R1, and when the locations of the first region R1 and the second region R2 are already determined structurally as with a MOSFET, the second region R2 has a shape in accordance with the structure. Further, although illustration is omitted, two, three, four, five or more first regions R1 may be present for one second region R2. For example, in a device including a circuit, when two or more portions (first region R1) of the circuit are irradiated with electron beams B, the portion where electrical conduction of the circuit can be observed will be considered as the second region R2.

In the position information setting step (ST1), when regions to be locally observed in the irradiation target S, for example, the positions of the first region R1 and the second region R2 of the irradiation target S are already determined by design, such as in a case of a MOSFET, the position information on the first region R1 and the second region R2 can be set based on this position information. Further, as described later, when the position information on the first region R1 and the second region R2 is not yet determined, detection data can be output by scanning the irradiation target S before the position information setting step (ST1), and the position information on the first region R1 and the second region R2 can be set based on the detection data.

In the first electron beam parameter setting step (ST2), the parameter of an electron beam to irradiate the first region R1 is set. The electron beam parameter can be suitably set in accordance with the purpose of observation. The electron beam parameter may be, for example, but is not limited to, the intensity of the electron beam (the intensity includes 0), the level of acceleration energy of the electron beam, the size of the electron beam, the shape of the electron beam, the irradiation duration of the electron beam, the emittance of the electron beam, or the like, to irradiate the first region R1.

An example of the control based on parameters set by the control unit 6 will be described with reference to FIG. 4. Note that the following description represents an example of the control. Control other than this example may be employed as long as it is within the scope of the technical concept disclosed in the present application. Further, to avoid complication of the drawing, a part of depiction for the circuit or the component may be omitted from the control unit 6.

First, the control performed when the parameter to be set is the intensity of the electron beam B will be described. Note that, in the present specification, “the intensity of an electron beam” means the level of the electron quantity (value of current) included in the irradiating electron beam B. The intensity of the electron beam B depends on the light amount of the excitation light L with which the photocathode 3 is irradiated. Therefore, when the intensity of the electron beam B is set as the parameter, the control unit 6 is only required to control the light amount of the excitation light L with which the photocathode 3 is irradiated so that the set intensity of the electron beam B is obtained. In the example illustrated in FIG. 1, the control unit 6 controls the light amount of the light source 2. Alternatively, a light amount adjustment device 61 such as a liquid crystal shutter may be provided between the light source 2 and the photocathode 3, and the amount of light reaching the photocathode 3 can be controlled by control of the liquid crystal shutter while the light amount of the light source 2 is maintained constant.

The level of the acceleration energy of the electron beam B can be controlled by changing the electric field intensity between the cathode 3 and the anode 4. The larger the voltage difference between the cathode 3 and the anode 4 is, the larger the acceleration energy will be. Therefore, when the level of the acceleration energy of the electron beam B is set as the parameter, the control unit 6 is only required to control the voltage of the power supply 7 so that the set intensity of the acceleration energy of the electron beam B is obtained.

The size of the electron beam B can be controlled by changing the size of the excitation light L that irradiates the photocathode 3. The larger the size of the excitation light L is, the larger the size of the electron beam B will be. Therefore, when the size of the electron beam B is set as the parameter, the control unit 6 is only required to control an excitation light size adjustment device 62 such as a lens or a liquid crystal shutter so that the set size of the electron beam B is obtained. Alternatively or optionally, additionally, an electron beam size adjustment device 63 such as an electromagnetic lens or an aperture may be provided on the optical axis of the emitted electron beam B, and the control unit 6 may control the electron beam size adjustment device 63. Further alternatively or optionally, additionally, the intermediate electrode 64 may be provided between the cathode 3 and the anode 4. The control unit 6 can adjust the focal position of the electron beam B when the electron beam B reaches the counterpart device 1b, in other words, can control the size of the electron beam B when the electron beam B reaches the target region R by (1) controlling the power supply 7 to adjust the potential differences between the cathode 3, the intermediate electrode 64, and the anode 4 or (2) controlling and moving the intermediate electrode 64 to adjust the relative positional relationship between the cathode 3, the intermediate electrode 64, and the anode 4. Note that the configuration of the intermediate electrode 64, the control method thereof, and the principle of enabling the focal position to be controlled are described in detail in Japanese U.S. Pat. No. 6,466,020. The contents disclosed in Japanese U.S. Pat. No. 6,466,020 is incorporated in the present application by reference.

The shape of the electron beam B can be controlled by providing an electron beam shape adjustment device 65 such as an electromagnetic lens or an aperture on the optical axis of the emitted electron beam B. Therefore, when the shape of the electron beam B is set as the parameter, the control unit 6 is only required to control the electron beam shape adjustment device 65 so that the set shape of the electron beam B is obtained. Alternatively, the shape of the electron beam B may be controlled by using the same device as the excitation light size adjustment device 62 such as a lens or a liquid crystal shutter to adjust the shape of the excitation light L that irradiates the photocathode 3.

The irradiation duration of the electron beam B can be controlled by an irradiation duration of the excitation light L emitted by the light source 2. Therefore, when the irradiation duration of the electron beam B is set as the parameter, the control unit 6 is only required to perform ON-OFF control on the light source 2 so that the set irradiation duration of the electron beam B is obtained. Alternatively, although illustration is omitted, a shutter may be provided between the light source 2 and the photocathode 3, and the control unit 6 may control the shutter to control the irradiation duration of the electron beam B.

The emittance of the electron beam B can be controlled by the wavelength of the excitation light L emitted by the light source 2. Therefore, when the emittance of the electron beam B is set as the parameter, the control unit 6 is only required to control the wavelength of the excitation light L so that the set emittance of the electron beam B is obtained. Although illustration is omitted, a known variable wavelength filter can be provided between the light source 2 and the photocathode 3, and the variable wavelength filter can be controlled by the control unit 6.

One or more of the electron beam parameters illustrated above as examples may be set in combination.

The electron beam irradiation condition first setting step (ST3) is to set irradiation conditions of the electron beam B that irradiates the first region R1 and has a first electron beam parameter and the electron beam B that irradiates the second region R2 based on the positional relationship between the first region R1 and the second region R2. In the first embodiment, as illustrated in FIG. 2, the irradiated region R is scanned with the electron beam B linearly by the electron beam deflector 8, and the scanning speed can be adjusted by the electron beam deflector 8. Therefore, when the first region R1 and the second region R2 are more distant from each other in their positional relationship than two regions in a positional relationship where a typical scanning speed with the electron beam B reaches from one to the other, the scanning speed with the electron beam B needs to be increased. In contrast, when the first region R1 and the second region R2 are closer to each other in their positional relationship than two positions in a positional relationship where a typical scanning speed with the electron beam B reaches from one to the other, the scanning speed with the electron beam B needs to be reduced. In other words, based on the positional relationship between the first region R1 and the second region R2, the electron beam irradiation condition first setting step (ST3) of the first embodiment is to set an irradiation timing of an electron beam that irradiates the first region R1 and has the first electron beam parameter and an irradiation timing of an electron beam that irradiates the second region R2 (hereafter, which may be referred to as “electron beam irradiation timing first setting step”). Note that, when the first region R1 and the second region R2 are in a positional relationship where a typical scanning speed of the electron beam B can reach from one to the other, scanning with the electron beam B can be performed at the typical scanning speed. In the electron beam irradiation condition first setting step (electron beam irradiation timing first setting step) (ST3) of the first embodiment, the irradiation timing of the electron beam B that irradiates the first region R1 and has the first electron beam parameter and the irradiation timing of the electron beam B that irradiates the second region R2 can be set based on the positional relationship between the first region R1 and the second region R2 and encompasses that the set result is the same as the typical scanning speed of the electron beam B.

The electron beam irradiation step (ST4) is to irradiate the first region R1 and the second region R2 with the electron beams B by the control unit 6 controlling the electron beam deflector 8 based on the timing set in the electron beam irradiation condition first setting step (ST3).

The detection step (ST5) is to determine, by the detector 5, the emission quantity of an emission substance SB emitted from the first region R1 and the second region R2 irradiated with the electron beams B and generate detection signals. Note that, although the first region R1 and the second region R2 are particularly focused on to describe parameters or irradiation timings of the electron beam B in the disclosure of the present application, naturally, other regions than the first region R1 and the second region R2 may also be irradiated with the electron beams B to perform detection of the emission substance SB.

In accordance with the electron beam applicator 1 and the local observation method according to the first embodiment, the following advantageous effects are achieved.

(1) When the first region R1 of the irradiation target S is irradiated with the electron beam B, the second region R2 affected by the irradiation can be observed.
(2) In inspection of an IC in which micro components are integrated, such as a MOSFET, it is difficult to locally observe whether or not an individual micro component itself such as a MOSFET is functioning properly. Thus, the conventional inspection on ICs is to test whether or not manufactured final ICs function properly or perform an operation test at a phase where ICs have been manufactured in a level enough to have contact with probes of probe testers. In contrast, the use of the electron beam applicator and the local observation method disclosed in the present application makes it possible to perform an operation test on individual micro components through local observation (inspection) at each phase during manufacturing. Therefore, at each phase in a manufacturing process, even when a defect or the like occur, the cause thereof can be identified.
(3) When a probe tester is used to inspect an inspection target such as an IC, it is required to contact the probe with the inspection target. Thus, an inspection target may be damaged by such contact with the probe. In contrast, the electron beam applicator and the local observation method disclosed in the present application enable observation (inspection) not involving physical contact with an inspection target, and thus, the inspection target is less likely to be damaged.

### Second Embodiment of Electron Beam Applicator and Second Embodiment of Local Observation Method

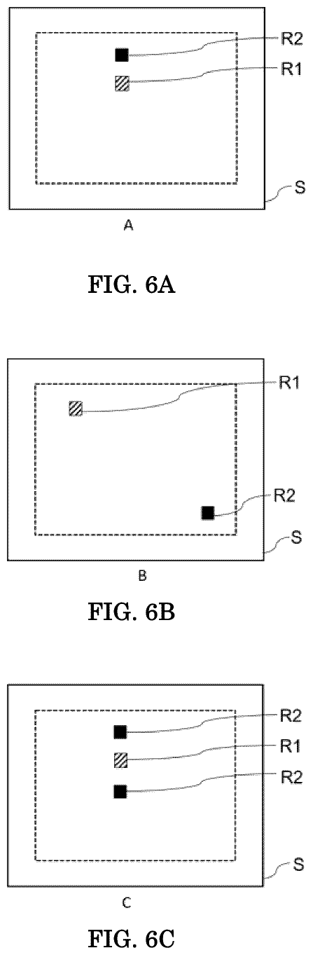

An electron beam applicator 1A and a local observation method according to the second embodiment will be described with reference to FIG. 1 to FIG. 6. FIG. 5 is an enlarged view of the part of the photocathode 3 of the electron beam applicator 1A according to the second embodiment. FIG. 6 represents diagrams of the irradiation target S when viewed from the photocathode 3 side.

The electron beam applicator 1A according to the second embodiment differs from the electron beam applicator 1 according to the first embodiment in that two or more different locations of the photocathode 3 are irradiated with the excitation light L from the light source so that two or more electron beams B are extracted from the photocathode 3 and is the same as the electron beam applicator 1 according to the first embodiment in other features. Accordingly, for the second embodiment, features different from those in the first embodiment will be mainly described, and repeated description for the features that have already been described in the first embodiment will be omitted. It is thus apparent that, even when not explicitly described in the second embodiment, any feature that has already been described in the first embodiment can be employed in the second embodiment.

To irradiate two or more different locations of the photocathode 3 with the excitation light L from the light source 2, a plurality of light sources 2 can be provided though illustration thereof is omitted. Alternatively, an excitation light divider such as a splitter, a spatial light phase modulator, or the like may be used to divide the excitation light L from a single light source 2 into two or more to irradiate the photocathode 3 therewith. Note that, when the electron beams B are extracted from two or more different locations of the photocathode 3, to determine the emission quantity of the emission substance SB by a single detector 5, the timings to irradiate the first region R1 and the second region R2 with the electron beams B can be shifted from each other. Further, when the first region R1 and the second region R2 are irradiated with the electron beams B at the same timing, multiple detectors 5 can be provided in accordance with the number of simultaneously irradiating electron beams B. Note that, although illustration is omitted, two or more photocathodes 3 may be provided, and the electron beams B may be extracted from different photocathodes 3, respectively.

In the local observation method according to the second embodiment, the position information setting step (ST1) and the first electron beam parameter setting step (ST2) can be performed in the same manner as in the first embodiment. In the electron beam irradiation condition first setting step (ST3), the irradiation timing of an electron beam that irradiates the first region R1 and has the first electron beam parameter and the irradiation timing of an electron beam that irradiates the second region R2 can be set based on the number of electron beams B extracted from the photocathode 3 in addition to the positional relationship between the first region R1 and the second region R2. Note that, when two or more first regions R1 and/or second regions R2 are present, a particular extracted electron beam B may be set to irradiate only one of the first regions R1 or the second regions R2 or may be set to irradiate both of the first regions R1 and the second regions R2. Further, in the second embodiment, a single electron beam deflector 8 may be used for performing scanning while deflecting two or more electron beams B, or a plurality of electron beam deflectors 8 may be provided in accordance with the number of extracted electron beams B. In the electron beam irradiation condition first setting step (ST3) according to the second embodiment, the irradiation timings of the electron beams B that irradiate the first region R1 and the second region R2 may be set also taking the number of electron beam deflectors 8 into consideration.

The electron beam irradiation step (ST4) is to irradiate the first region R1 and the second region R2 with the electron beams B by the control unit 6 controlling one or two or more electron beam deflectors 8 based on the timings set in the electron beam irradiation condition first setting step (ST3).

The electron beam applicator 1A and the local observation method according to the second embodiment can irradiate an irradiation target with a plurality of electron beams B. Therefore, in addition to the advantageous effects achieved by the electron beam applicator 1 and the local observation method according to the first embodiment, the following advantageous effect is achieved.

(1) In the electron beam applicator 1 and the local observation method according to the first embodiment, it is possible to adjust the timing to irradiate the first region R1 and the second region R2 with the electron beams B by adjusting the scanning speed of the electron beam deflector 8. However, when a single irradiating electron beam B is used, the irradiated region R is in general scanned linearly with the electron beam B as illustrated in FIG. 2. Therefore, when the second region R2 is present upstream in the scanning direction from the first region R1 as illustrated in FIG. 6A, when the first region R1 and the second region R2 are far different from each other as illustrated in FIG. 6B, and when a plurality of second regions R2 are present for the first region R1 as illustrated in FIG. 6C, it may be difficult to cope with these cases by mere adjustment of the scanning speed of the electron beam deflector 8. Further, although illustration is omitted, when two or more first regions R1 are present for one second region R2, it may be difficult to irradiate the two or more first regions R1 with the electron beams B at suitable timings. In contrast, the electron beam applicator 1A and the local observation method according to the second embodiment can irradiate the irradiation target S with a plurality of electron beams B and thus can cope with various positional relationships between the first region R1 and the second region R2.

### Third Embodiment of Electron Beam Applicator and Third Embodiment of Local Observation Method

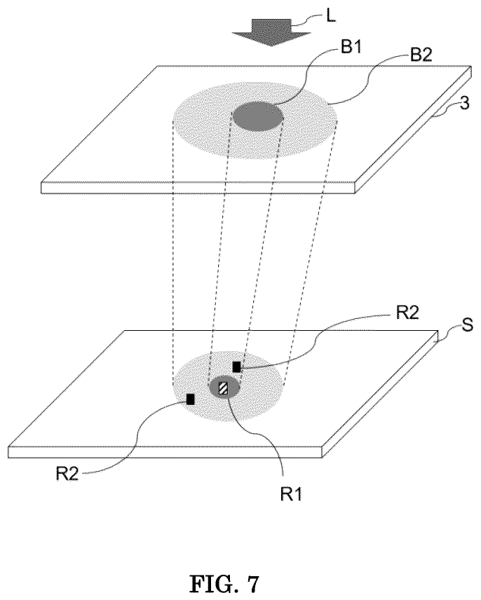

An electron beam applicator 1B and a local observation method according to the third embodiment will be described with reference to FIG. 1 to FIG. 4 and FIG. 7. FIG. 7 is an enlarged view of the part of the photocathode 3 of the electron beam applicator 1B and the irradiation target S according to the third embodiment.

The electron beam applicator 1B according to the third embodiment does not use the electron beam deflector 8 and thus is of a non-scan type, which differs from the electron beam applicators 1 and 1A according to the first and second embodiments, and other features are the same as those of the electron beam applicators 1 and 1A according to the first and second embodiments. Accordingly, for the third embodiment, features different from those in the first and second embodiments will be mainly described, and repeated description for the features that have already been described in the first and second embodiments will be omitted. It is thus apparent that, even when not explicitly described in the third embodiment, any feature that has already been described in the first and second embodiments can be employed in the third embodiment.

As illustrated in FIG. 7, in the electron beam applicator 1B according to the third embodiment, an electron beam B1 having the first electron beam parameter and having a size and/or a shape that can cover the first region R1 and an electron beam B2 having a size and/or a shape that can cover the second region R2 are extracted from the photocathode 3. Note that a converging device (illustration is omitted) that converges the electron beams B1, B2, the electron beam size adjustment device 63, the intermediate electrode 64, the electron beam shape adjustment device 65, or the like may be included between the photocathode 3 and the irradiation target S. When the electron beams B1, B2 are extracted from the photocathode 3, the size and/or the shape of the excitation light L to irradiate the photocathode 3 can be adjusted also taking the converging device, the electron beam size adjustment device 63, the intermediate electrode 64, the electron beam shape adjustment device 65, or the like into consideration.

When the electron beams B1 and B2 illustrated in FIG. 7 are formed from a single light source 2, a spatial light phase modulator can be used to divide excitation light into two or more excitation lights L having different phases. By modulating the phase, it is possible to change the intensities of the electron beams B1 and B2. Other electron beam parameters such as the size or the shape of electron beams can be adjusted in the same manner as in the first embodiment. Further, although the example in which the electron beams B1 and B2 having different intensities are emitted from the single light source 2 to the irradiation target S is illustrated in the example illustrated in FIG. 7, two or more light sources 2 may be provided, and the electron beams B1 and B2 may be emitted from respective light sources 2 to the irradiation target S.

In the local observation method according to the third embodiment, the position information setting step (ST1) and the first electron beam parameter setting step (ST2) can be performed in the same manner as in the first embodiment. The electron beam irradiation condition first setting step (ST3) is to set the size and/or the shape of an electron beam that irradiates the first region R1 and has the first electron beam parameter and the size and/or the shape of an electron beam that irradiates the second region R2 based on the positional relationship between the first region R1 and the second region R2 (hereafter, which may be referred to as “electron beam irradiation size and/or shape first setting step”).

In the electron beam irradiation step (ST4), the control unit 6 can control one or more selected from the light amount adjustment device 61, the excitation light size adjustment device 62, the electron beam size adjustment device 63, the intermediate electrode 64, the electron beam shape adjustment device 65, and the like as needed in addition to the spatial light phase modulator so that the size and/or the shape of the electron beam set in the electron beam irradiation condition first setting step (ST3) is obtained.

Note that the electron beam applicator 1B according to the third embodiment can be used for both of the reflection type and the transmission type, and when used as the transmission type, transmitted electrons, scattered electrons (inelastic/elastic) can be detected as the emission substance SB in the detection step (ST5).

The electron beam applicator 1B and the local observation method according to the third embodiment achieve the following advantageous effects in addition to the advantageous effects achieved by the electron beam applicator 1 and the local observation method according to the first embodiment.

(1) Since the first region R1 and the second region R2 can be irradiated with the electron beams B at the same time, no time lag due to scanning with the electron beams B occurs. Therefore, even when an effect on the second region R2 appears immediately after the first region R1 is irradiated with the electron beam B, such an effect can be observed.
(2) In the conventional non-scan type electron beam applicator, the irradiation target S is irradiated with the electron beam B having the same electron beam parameter. In contrast, in the third embodiment, the first region R1 can be irradiated with an electron beam having an electron beam parameter set in advance. Therefore, for example, it is possible to observe diffusion of atoms, a change in crystal structure, a defect, or the like caused by local heating applied to a grain interior, a grain boundary, a crystal interface, a dislocation, or the like. Further, it is possible to observe denaturation or structural changes caused by local heating of biological samples or proteins.

The electron beam applicator 1 may be, for example, a scanning electron microscope, an electron beam inspection device, an X-ray analyzer, a transmission electron microscope, a scanning transmission electron microscope, or the like. Since the electron beam applicators 1 and 1A according to the first and second embodiments are of the scan type, they may be a scanning electron microscope, an electron beam inspection device, an X-ray analyzer, a scanning transmission electron microscope, or the like. Since the electron beam applicator 1B according to the third embodiment is of the non-scan type, it may be an electron beam inspection device, an X-ray analyzer, a transmission electron microscope, or the like.

### Examples of Configuration Applicable to Embodiments of Electron Beam Applicators and Local Observation Methods

Next, examples of the configuration applicable to the electron beam applicators 1, 1A, and 1B and the local observation methods according to the above first, second, and third embodiments will be described. Note that, while the following description will be provided as description of steps of the local observation method, the description corresponds to the control details of the control unit 6 in a case of the electron beam applicators 1, 1A, and 1B. Further, unless otherwise specified, applicable configuration examples described below are applicable to any of the first to third embodiments. When the embodiment to which the configuration is applicable is limited, the embodiment to which the configuration is applicable will be indicated in the description of the applicable configuration examples.

### First Region and Second Region Position Information Acquisition Step

The local observation method may perform a first region and second region position information acquisition step before the position information setting step (ST1). The first region and second region position information acquisition step is to perform a step of irradiating the irradiation target S with the electron beam B, a detection step of determining, by the detector 5, the emission quantity of an emission substance SB emitted from the irradiated region R irradiated with the electron beam B and generating a detection signal, and a detection data output step of outputting the detection signal generated in the detection step in association with the position information on the irradiated region R (for example, information on scanning performed by the electron beam deflector 8 in the first and second embodiments, and information on an irradiation position of the electron beam B in the third embodiment). The position information setting step (ST1) is then performed based on the detection data associated with the position information on the irradiated region R output in the detection data output step.

When the first region and second region position information acquisition step is implemented, an advantageous effect is achieved that it is possible to acquire the position information on the first region R1 and the second region R2 by actually irradiating the irradiated region R with the electron beams B even when the designed position information on the first region R1 and the second region R2 of the irradiated region R is unknown.

### Electron Beam Irradiation Timing First Setting Step (ST3)

In the first and second embodiments, the electron beam irradiation timing first setting step (ST3) of the local observation method may set an irradiation timing of the electron beam B having the first electron beam parameter that irradiates the first region R1 and an irradiation timing of the electron beam B that irradiates the second region R2 based on the time of appearance of an effect on the second region R2 and the duration of the effect after the first region R1 is irradiated with an electron beam in addition to the positional relationship between the first region R1 and the second region R2. It is expected for some irradiation targets S that there is a difference in the duration of appearance of an effect on the second region R2 caused by irradiation of the first region R1 with the electron beam B. Further, it is also expected that some effects may continue after appearance and other effects may disappear immediately after appearance. In the first electron beam irradiation timing setting step (ST3), when not only the positional relationship between the first region R1 and the second region R2 but also the time of appearance of an effect and the duration of the effect are taken into consideration, an advantageous effect that the effect on the second region R2 can be more precisely observed is achieved.

### Observation-Use Electron Beam Parameter Setting Step

The local observation method may include an observation-use electron beam parameter setting step of setting the parameter of the electron beam B that irradiates the second region R2. In the local observation method disclosed in the present application, the parameter of the electron beam B to irradiate a region other than the first region R1 may be the same as long as it is possible to observe the effect on the second region R2 caused by irradiation of the first region R1 with the electron beam B having the first electron beam parameter. Alternatively, when the effect on the second region R2 is large, a parameter of the electron beam B to irradiate the second region R2 may be set in order to more precisely observe the effect on the second region R2. For example, in a case of nMOS described above, it may be required to irradiate the first region R1 with a high-power electron beam B in order to activate the gate, which is the first region R1, in the nMOS having a large capacitance. In such a case, since more electrons move to the drain, which is the second region R2, the second region R2 of an observed SEM image may be overexposed. In such a case, the second region R2 needs to be irradiated with an observation-use electron beam set as a weakened electron beam B (with a reduced value of current). Contrarily, when electrons moving to the second region R2 is reduced, an observation-use electron beam parameter needs to be set so that the power of the electron beam B to irradiate the second region R2 is increased. While the observation-use electron beam parameter differs in accordance with the type of the irradiation target S or the like, the same parameter as the first electron beam parameter can be used in terms of the type of the electron beam parameter to be set. When the observation-use electron beam parameter is set, an advantageous effect that an effect on the second region R2 can be precisely observed is achieved.

### Repetition of Local Observation Method

After performing the local observation method according to the first to third embodiments, the control unit 6 may implement control to perform:
a second electron beam parameter setting step of, for a parameter of an electron beam B that irradiates the first region R1, setting an electron beam parameter different from the parameter set in the first electron beam parameter setting step;
an electron beam irradiation condition second setting step of, based on the positional relationship between the first region R1 and the second region R2, setting irradiation conditions of an electron beam B that irradiates the first region R1 and has a second electron beam parameter and an electron beam B that irradiates the second region R2 (more specifically, “electron beam irradiation timing second setting step” in the first and second embodiments, and “electron beam irradiation size and/or shape second setting step” in the third embodiment);
an electron beam irradiation step of irradiating the first region R1 and the second region R2 with electron beams B based on the irradiation conditions set in the electron beam irradiation condition second setting step; and
a detection step of determining, by the detector 5, an emission quantity of an emission substance SB emitted from the first region R1 and the second region R2 irradiated with the electron beams B and generating a detection signal.

For some types of the irradiation target S or some purposes of observation, it may be intended to observe not only whether or not there is an effect on the second region R2 but also how the effect on the second region R2 changes when the first region R1 is irradiated with the electron beam B having a different parameter. Repeatedly performing the local observation method of irradiating the first region R1 with the electron beam B having a different parameter achieves an advantageous effect that it is possible to observe a change in the second region R2. Note that, when a plurality of first regions R1 are present, in repeatedly performing the local observation method, the parameters of the electron beams B that irradiate respective first regions R1 at each time the local observation method is performed may be the same or different from each other.

Note that any one or more of the applicable configuration examples in the embodiments of the electron beam applicators 1, 1A, 1B and the local observation method described above may be combined.

### Embodiment of Program and Storage Medium

The embodiments of the electron beam applicators 1, 1A, 1B and the local observation method described above and the applicable configuration examples in the embodiments can be implemented by control of the control unit 6 of the electron beam applicators 1, 1A, 1B. Therefore, a program prepared to enable each step illustrated in FIG. 4 (including the applicable configuration examples) to be performed needs to be installed in the control unit 6. Further, the program may be stored in and provided as a readable storage medium. The program disclosed in the present application is installed in the control unit 6 of the conventional electron beam applicators 1, 1A, 1B, and thereby the local observation method disclosed in the present application can be implemented.

Although Examples will be presented below to specifically describe the embodiment disclosed in the present application, these Examples are only for the purpose of illustration of the embodiment and are not intended to limit or restrict the scope of the invention disclosed in the present application.

### EXAMPLES

### Fabrication of Electron Beam Applicator 1

### Example 1

A laser source (iBeamSmart by Toptica) was used for the light source 2. For the photocathode 3, an InGaN photocathode was fabricated by a known method described in Daiki SATO et al. 2016 Jpn. J. Appl. Phys. 55 05FH05. EA treatment on the photocathode surface was performed in accordance with a known method. An electron gun portion of a commercially available SEM was replaced with the fabricated electron gun portion. Note that, in the specification of the commercially available SEM, a cold field emission electron source (CFE) was used for the electron gun, and a deflection coil was provided as the electron beam deflector 8. Electron beam acceleration voltage of 30 kv at the maximum and observation at magnification of 1 million times at the maximum are possible. The program was created and improved so that the control unit 6 of the electron beam applicator 1 can implement each step described in the embodiment.

### Implementation of Local Observation Method

### Example 2

### Preparation of Sample

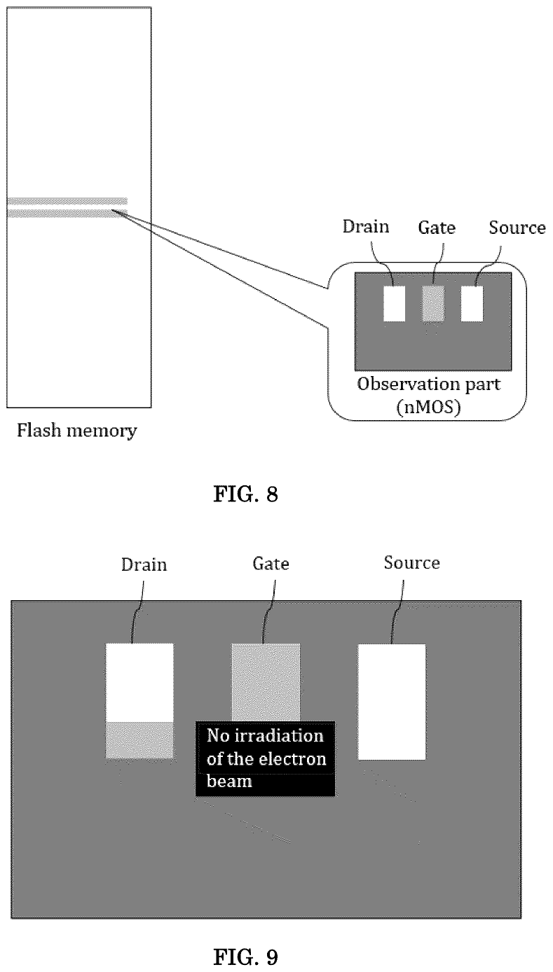

A commercially available flash memory was destroyed and ground to expose a micro nMOS. FIG. 8 illustrates a view of the prepared sample.

### Local Observation Performed on nMOS

The overview of the observation of nMOS through the local observation method disclosed in the present application will be described with reference to FIG. 8. In typical SEM, an electron beam B with an even intensity is emitted within a field of view. In other words, an nMOS is irradiated with an electron beam B having an even electron amount. In low voltage SEM, an electrically isolated part generates a potential difference contrast (VC) due to positive charge accumulation and is darkened. In the nMOS illustrated in FIG. 8, only the gate out of the drain, the gate, and the source (ground) is electrically isolated and in a positive charge accumulated state. With a sufficient potential of the positive charge accumulation in the gate, electrons move from the source to the drain. In Example 2, while changing the intensity of the electron beam B that irradiates the gate, a state of electrons moving from the source to the drain was observed.

The electron beam applicator 1 produced in Example 1 was used to irradiate the sample with an electron beam B in the following conditions.
Acceleration voltage: 0.8 kV
Magnification: 3000×
First electron beam parameter for irradiation of the first region (gate): For comparison of the effect of the local observation method, two values of irradiation current were set, one causing no irradiation of the electron beam, and the other allowing a potential difference of 3 V to be provided to the gate were set.
Electron beam irradiation condition first setting: Based on the positional relationship between the source, the drain, and the gate, irradiation timings of the electron beams B to irradiate the first region and the second region were set.

FIG. 9 illustrates an overview of the local observation method of Example 2. In Example 2, in the “Gate” illustrated in FIG. 9, the upper part was irradiated with the electron beam B having the value of irradiation current that allows a potential difference of 3 V to be provided, and the lower part, which is a part indicated by “No irradiation of electron beam”, was not irradiated with the electron beam B. When a SEM image was captured, the drain adjacent to the gate not irradiated with the electron beam B was darkened. This is considered to be due to the fact that the drain to which electrons no longer moved from the source was electrically isolated and VC occurred. On the other hand, the drain adjacent to the gate irradiated with the electron beam B was brightened. From the above result, it was confirmed that irradiation of the gate, which is the first region R1, with the electron beam B having a predetermined electron beam parameter enables observation as to whether or not the drain, which is the second region R2, is affected.

### Example 3

Next, eight types of the first electron beam parameters with different values of irradiation current were set so that potential differences from 0 V to 3 V can be applied to the gate, and the drain when different portions of the gate were irradiated with electron beams B of different intensities (the intensity of the electron beam for observing the drain was the same) was observed in the same procedure as in Example 2.

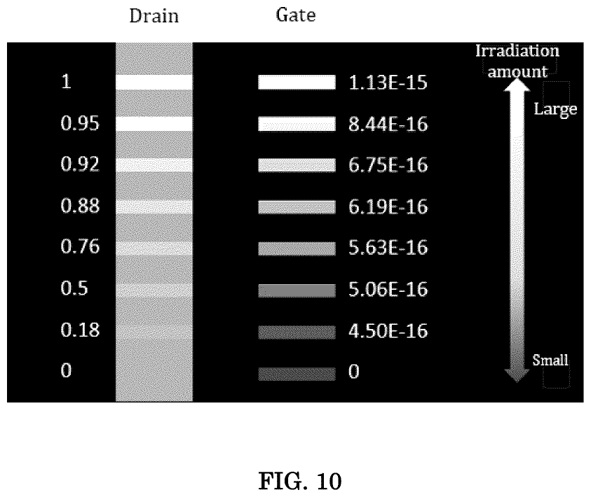

FIG. 10 illustrates the result obtained from SEM images when the local observation method of Example 3 was performed. In FIG. 10, numerical values on the right of the gate represent the charge amount (coulomb) with which the gate was irradiated. Note that the numerical values on the right of the gate are the values when the lowermost brightness of the gate is set to zero. Further, in FIG. 10, numerical values on the left of the drain represent the brightness of the SEM image when the gate was irradiated with the charge amount and are relative values when the value for the brightest SEM image is defined as 1. As is clear from FIG. 10, when the gate was irradiated with the electron beam B having a larger value of current (charge amount), the SEM image of the drain was brighter. This means that a larger value of current (charge amount) with which the gate is irradiated results in a larger number of electrons moving from the source to the drain. From the above result, it was confirmed that, when the first region R1 is irradiated with the electron beam B, the local observation method disclosed in the present application enables observation as to not only whether or not there is an effect on the second region R2 but also how the effect on the second region changes.

### INDUSTRIAL APPLICABILITY

With the electron beam applicators and the local observation methods using these electron beam applicators disclosed in the present application, when irradiating a first region of an irradiation target with an electron beam, it is possible to observe a second region affected by the irradiation. Therefore, the electron beam applicators and the local observation methods using these electron beam applicators disclosed in the present application are useful for manufacturers of electron microscopes, electron beam inspection devices, or the like and business entities that perform inspection, observation, or the like on irradiation targets.

### List of Reference Symbols

1, 1A, 1B electron beam applicator
1a electron gun portion
1b counterpart device
2 light source
3 photocathode (cathode)
4 anode
5 detector
6 control unit
61 light amount adjustment device
62 excitation light size adjustment device
63 electron beam size adjustment device
64 intermediate electrode
65 electron beam shape adjustment device
7 power supply
8 electron beam deflector
B, B1, B2 electron beam
CB vacuum chamber
L excitation light
R irradiated region
R1 first region
R2 second region
S irradiation target
SB emission substance
ST1 position information setting step
ST2 first electron beam parameter setting step
ST3 electron beam irradiation condition first setting step
ST4 electron beam irradiation step
ST5 detection step

1. A local observation method for an irradiation target in an electron beam applicator, the local observation method being a method for, when irradiating a first region of the irradiation target with an electron beam, observing a second region affected by the irradiation,
wherein the electron beam applicator includes
a light source,
a photocathode configured to generate releasable electrons in response to receiving excitation light emitted from the light source,
an anode configured to form an electric field between the photocathode and the anode and extract the releasable electrons by the formed electric field to form an electron beam,
a detector configured to detect an emission substance emitted from the irradiation target irradiated with the electron beam and generate a detection signal, and
a control unit, and
wherein the local observation method implements control such that the control unit performs:
a position information setting step of setting position information on the first region and the second region in the irradiation target;
a first electron beam parameter setting step of setting a parameter of an electron beam that irradiates the first region;
an electron beam irradiation condition first setting step of, based on a positional relationship between the first region and the second region, setting irradiation conditions of an electron beam that irradiates the first region and has a first electron beam parameter and an electron beam that irradiates the second region;
an electron beam irradiation step of irradiating the first region and the second region with electron beams based on the irradiation conditions set in the electron beam irradiation condition first setting step; and
a detection step of determining, by the detector, an emission quantity of an emission substance emitted from the first region and the second region irradiated with the electron beams and generating a detection signal.

2. The local observation method according to claim 1 further comprising a first region and second region position information acquisition step before the position information setting step,
wherein the first region and second region position information acquisition step performs:
a step of irradiating the irradiation target with an electron beam,
a detection step of determining, by the detector, an emission quantity of an emission substance emitted from an irradiated region irradiated with the electron beam and generating a detection signal, and
a detection data output step of outputting the detection signal generated in the detection step in association with position information on the irradiated region, and
wherein the position information setting step is performed based on detection data associated with the position information on the irradiated region output in the detection data output step.

3. The local observation method according to claim 1,
wherein the electron beam applicator further includes an electron beam deflector configured to scan the irradiation target with the electron beam, and
wherein the control unit,
in the electron beam irradiation condition first setting step,
performs an electron beam irradiation timing first setting step of, based on the positional relationship between the first region and the second region, setting an irradiation timing of an electron beam that irradiates the first region and has a first electron beam parameter and an irradiation timing of an electron beam that irradiates the second region, and
in the electron beam irradiation step,
irradiates the first region and the second region with electron beams at timings set in the electron beam irradiation timing first setting step by controlling the electron beam deflector.

4. The local observation method according to claim 2,
wherein the electron beam applicator further includes an electron beam deflector configured to scan the irradiation target with the electron beam, and
wherein the control unit,
in the electron beam irradiation condition first setting step,
performs an electron beam irradiation timing first setting step of, based on the positional relationship between the first region and the second region, setting an irradiation timing of an electron beam that irradiates the first region and has a first electron beam parameter and an irradiation timing of an electron beam that irradiates the second region, and
in the electron beam irradiation step,
irradiates the first region and the second region with electron beams at timings set in the electron beam irradiation timing first setting step by controlling the electron beam deflector.

5. The local observation method according to claim 3, wherein the electron beam irradiation timing first setting step sets,
based on a time of appearance of an effect on the second region and a duration of the effect after the first region is irradiated with an electron beam in addition to the positional relationship between the first region and the second region,
an irradiation timing of an electron beam that irradiates the first region and has a first electron beam parameter and an irradiation timing of an electron beam that irradiates the second region.

6. The local observation method according to claim 1 further comprising an observation-use electron beam parameter setting step of setting a parameter of an electron beam that irradiates the second region.

7. The local observation method according to claim 1, wherein an electron beam with which the first region is irradiated and an electron beam with which the second region is irradiated are
extracted from different locations of a single photocathode, or
extracted from different photocathodes.

8. The local observation method according to claim 1, wherein the control unit,
in the electron beam irradiation condition first setting step,
performs an electron beam irradiation size and/or shape first setting step of, based on the positional relationship between the first region and the second region, setting a size and/or a shape of an electron beam that irradiates the first region and has a first electron beam parameter and a size and/or a shape of an electron beam that irradiates the second region, and
in the electron beam irradiation step,
irradiates the first region and the second region with electron beams having sizes and/or shapes set in the electron beam irradiation size and/or shape first setting step.

9. The local observation method according to claim 2, wherein the control unit,
in the electron beam irradiation condition first setting step,
performs an electron beam irradiation size and/or shape first setting step of, based on the positional relationship between the first region and the second region, setting a size and/or a shape of an electron beam that irradiates the first region and has a first electron beam parameter and a size and/or a shape of an electron beam that irradiates the second region, and
in the electron beam irradiation step,
irradiates the first region and the second region with electron beams having sizes and/or shapes set in the electron beam irradiation size and/or shape first setting step.

10. The local observation method according to claim 1, wherein the local observation method implements control such that, after performing the detection step according to claim 1, the control unit performs:
a second electron beam parameter setting step of, for a parameter of an electron beam that irradiates the first region, setting an electron beam parameter different from the parameter set in the first electron beam parameter setting step;
an electron beam irradiation condition second setting step of, based on the positional relationship between the first region and the second region, setting irradiation conditions of an electron beam that irradiates the first region and has a second electron beam parameter and an electron beam that irradiates the second region;
an electron beam irradiation step of irradiating the first region and the second region with electron beams based on the irradiation conditions set in the electron beam irradiation condition second setting step; and
a detection step of determining, by the detector, an emission quantity of an emission substance emitted from the first region and the second region irradiated with the electron beams and generating a detection signal.

11. The local observation method according to claim 1,
wherein the irradiation target is a metal oxide semiconductor field effect transistor,
wherein the first region is the gate,
wherein the second region is the drain, and
wherein a state of current flowing between the source and the drain is observed by irradiating the first region with an electron beam.

12. The local observation method according to claim 1, wherein the electron beam applicator is
a scanning electron microscope,
an electron beam inspection device,
an X-ray analyzer,
a transmission electron microscope, or
a scanning transmission electron microscope.

13. A program that causes the control unit of the electron beam applicator to perform each step according to claim 1.

14. A computer readable storage medium storing the program according to claim 13.

15. An electron beam applicator comprising:
a light source;
a photocathode configured to generate releasable electrons in response to receiving excitation light emitted from the light source;
an anode configured to form an electric field between the photocathode and the anode and extract the releasable electrons by the formed electric field to form an electron beam;
a detector configured to detect an emission substance emitted from an irradiation target irradiated with the electron beam and generate a detection signal; and
a control unit,
wherein the program according to claim 13 is stored in the control unit.

16. A program that causes the control unit of the electron beam applicator to perform each step according to claim 2.

17. A program that causes the control unit of the electron beam applicator to perform each step according to claim 3.

18. A program that causes the control unit of the electron beam applicator to perform each step according to claim 4.

19. A program that causes the control unit of the electron beam applicator to perform each step according to claim 5.

20. A program that causes the control unit of the electron beam applicator to perform each step according to claim 6.
